(19) United States
(12) Patent Application Publication
(10) Pub. No.: US 2026/0271349 A1
(43) Pub. Date: Sep. 10, 2026

(54) SEMICONDUCTOR DEVICE AND A METHOD OF MANUFACTURING A SEMICONDUCTOR DEVICE

(71) Applicants: HYUNDAI MOTOR COMPANY, Seoul (KR); KIA CORPORATION, Seoul (KR)

(72) Inventors: Nack Yong Joo, Hwaseong-si (KR); Dae Hwan Chun, Hwaseong-si (KR); Jungyeop Hong, Hwaseong-si (KR); Taehyun Kim, Hwaseong-si (KR); Youngkyun Jung, Hwaseong-si (KR); Junghee Park, Hwaseong-si (KR)

(73) Assignees: HYUNDAI MOTOR COMPANY, Seoul (KR); KIA CORPORATION, Seoul (KR)

(21) Appl. No.: 19/247,683

(22) Filed: Jun. 24, 2025

(30) Foreign Application Priority Data
Mar. 10, 2025 (KR) 10-2025-0030395

(51) Int. Cl. H10D 62/10; H10D 30/01; H10D 30/65; H10D 62/00

(52) U.S. Cl. CPC H10D 62/109; H10D 30/0281; H10D 30/65; H10D 62/052; H10D 62/054

(57) ABSTRACT

A semiconductor device includes a substrate, a first p type layer and an n− type epitaxial layer located on the substrate, an n+ type layer and a second p type layer located on the n− type epitaxial layer, a protection layer located on the n+ type layer and the second p type layer, and a gate located on the protection layer and on the second p type layer.

### CROSS-REFERENCE TO RELATED APPLICATION

This application claims priority to and the benefit of Korean Patent Application No. 10-2025-0030395, filed with the Korean Intellectual Property Office on Mar. 10, 2025, the entire contents of which are hereby incorporated herein by reference.

### BACKGROUND

### (a) Technical Field

The present disclosure relates to a semiconductor device and a method of manufacturing a semiconductor device. More specifically, the disclosure relates to a semiconductor device and a method of manufacturing a semiconductor device with an increased breakdown voltage.

### (b) Description of the Related Art

Transistor devices (e.g., MOSFET, JFET, MESFET, IGBT, or the like) are three-terminal devices that can conduct current by controlling the gate terminal. Power semiconductor transistors for switching require high voltage and large current.

Transistor devices have different electrical characteristics depending on their structure, and appropriate devices are used depending on the application. However, the transistor devices commonly require high current density, low turn-on voltage, high breakdown voltage, low leakage current, and fast switching speed. These electrical characteristics form a trade-off relationship. Therefore, structures are continuously being studied to improve one or more characteristics while maintaining other characteristics, by weakening the trade-off relationship. In particular, in ultrawide bandgap (UWB) materials such as Ga₂O₃, AlN, and diamond, horizontal structures, rather than vertical structures, are being studied due to high critical electric fields, and research is actively being conducted to improve the characteristics of horizontal power semiconductors.

The matters described in this Background section are only intended to enhance understanding of the background of the present disclosure. Therefore, the Background section may contain information that does not form prior art that is already known to those having ordinary skill in the art to which the present disclosure pertains.

### SUMMARY

Embodiments of the present disclosure provide a semiconductor device and a method of manufacturing a semiconductor device with an increased breakdown voltage by alleviating the electric field concentration concentrated at an end portion of a gate or a P-type layer of a lower portion of a gate.

According to an embodiment, a semiconductor device is provided. The semiconductor device includes a substrate, a first p type layer and an n− type epitaxial layer located on the substrate, an n+ type layer and a second p type layer located on the n− type epitaxial layer, a protection layer located on the n+ type layer and the second p type layer, and a gate located on the protection layer and on the second p type layer.

The semiconductor device may further include an insulation layer, where the insulation layer is located between the second p type layer and the gate and between the protection layer and the gate.

A portion of a lower surface of the insulation layer may be in contact with an upper surface of the second p type layer, and another portion of the lower surface of the insulation layer may be in contact with an upper surface of the protection layer, and a portion of an upper surface of the insulation layer may be in contact with a lower surface of the gate.

A lower surface of the first p type layer may be in contact with an upper surface of the substrate, and an upper surface of the first p type layer may be in contact with a portion of a lower surface of the n− type epitaxial layer.

The first p type layer may be located in a lower portion relative to the second p type layer in a thickness direction of the semiconductor device, interposing the n− type epitaxial layer.

The protection layer may be divided by the gate.

The semiconductor device may further include a source electrode located on the protection layer and the n+ type layer, where a portion of a lower surface of the source electrode may be in contact with an upper surface of the protection layer, and another portion of the lower surface of the source electrode may be in contact with an upper surface of the n+ type layer.

The semiconductor device may further include a drain electrode located on the protection layer and the n+ type layer, where a portion of a lower surface of the drain electrode may be in contact with an upper surface of the protection layer, and another portion of the lower surface of the drain electrode may be in contact with an upper surface of the n+ type layer.

The semiconductor device may further include a buffer layer located between the substrate and the n− type epitaxial layer, wherein a lower surface of the first p type layer and a portion of an upper surface of the buffer layer are in contact with the n− type epitaxial layer.

According to another embodiment, a method of manufacturing a semiconductor device is provided. The method includes providing a substrate, forming an n− type epitaxial layer and a first p type layer on the substrate, forming n+ type layer and a second p type layer on the n− type epitaxial layer, forming a protection layer on the n+ type layer and the second p type layer, and partially removing the protection layer located on the second p type layer, and forming a gate on the second p type layer and on the protection layer.

Forming the n− type epitaxial layer and the first p type layer on the substrate may include forming the n− type epitaxial layer by growing an epitaxial layer on the substrate, forming the first p type layer by injecting ions into a portion of the n− type epitaxial layer, and re-growing the epitaxial layer on the n− type epitaxial layer and the first p type layer.

Forming the n− type epitaxial layer and the first p type layer on the substrate may include forming the first p type layer on the substrate, partially removing the first p type layer, and forming the n− type epitaxial layer by growing an epitaxial layer on a remaining first p type layer and the substrate.

Forming the n− type epitaxial layer and the first p type layer on the substrate may include forming the first p type layer on the substrate, forming the n− type epitaxial layer by injecting ions into a portion of the first p type layer, and forming the n− type epitaxial layer by growing the epitaxial layer on a remaining first p type layer and the n− type epitaxial layer.

The method may further include, before forming the gate, forming an insulation layer on the second p type layer and on the protection layer, where the forming the gate forms the gate on the insulation layer.

The method may further include forming a source electrode on the protection layer and the n+ type layer and forming a drain electrode on the protection layer and the n+ type layer.

The method may further include, after the providing the substrate, forming a buffer layer on the substrate.

A semiconductor device according to an embodiment may improve a breakdown voltage by alleviating the electric field concentration.

A semiconductor device according to an embodiment may increase the degree of design freedom of the epitaxial region.

### BRIEF DESCRIPTION OF THE DRAWINGS

FIG. 1 is a drawing schematically showing a semiconductor device according to an embodiment.

FIG. 2 is a drawing schematically showing a semiconductor device in a device-on state, according to an embodiment.

FIG. 3 is a drawing schematically showing a semiconductor device in a device-off-state, according to an embodiment.

FIG. 4 is a drawing schematically showing forming an n− type epitaxial layer and a first p type layer, in a method of manufacturing a semiconductor device according to an embodiment.

FIG. 5 is a drawing schematically showing forming an n− type epitaxial layer and a first p type layer, in a method of manufacturing a semiconductor device according to another embodiment.

FIG. 6 is a drawing schematically showing forming an n− type epitaxial layer and a first p type layer, in a method of manufacturing a semiconductor device according to still another embodiment.

FIG. 7 is a drawing schematically showing processes after forming an n-type epitaxial layer and a first p type layer, in a method of manufacturing a semiconductor device according to an embodiment.

FIG. 8 is a drawing schematically showing forming a second p type layer, in a method of manufacturing a semiconductor device according to an embodiment.

FIG. 9 is a drawing schematically showing forming an n+ type layer, in a method of manufacturing a semiconductor device according to an embodiment.

FIG. 10 is a drawing schematically showing forming a protection layer, in a method of manufacturing a semiconductor device according to an embodiment.

FIG. 11 is a drawing schematically showing forming an insulation layer, in a method of manufacturing a semiconductor device according to an embodiment.

FIG. 12 is a drawing schematically showing forming a gate, a drain electrode and a source electrode, in a method of manufacturing a semiconductor device according to an embodiment.

FIG. 13 shows measurement results of a state current (a), a threshold voltage (b), and a breakdown voltage (c), in an embodiment.

### DETAILED DESCRIPTION

Embodiments of the present disclosure are described in detail hereinafter with reference to the accompanying drawings to enable a person of ordinary skill in the art may to implement the disclosure. As those having ordinary skill in the art would realize, the described embodiments may be modified in various different ways, without departing from the spirit or scope of the present disclosure. In order to clarify the present disclosure, parts that are not related to the description have been omitted, and the same elements or equivalents are referred to with the same reference numerals throughout the specification.

In addition, unless explicitly described to the contrary, the word “comprise” and variations such as “comprises” or “comprising” will be understood to imply the inclusion of stated elements but not the exclusion of any other elements. Terms including an ordinary number, such as first and second, are used for describing various constituent elements, but the constituent elements are not limited by the terms. The terms are only used to differentiate one component from other components.

In the present disclosure, when a component, controller, device, element, apparatus, unit or the like of the present disclosure is described as having a purpose or performing an operation, function, or the like, the component, controller, device, element, apparatus, unit or the like should be considered herein as being “configured to” meet that purpose or to perform that operation or function.

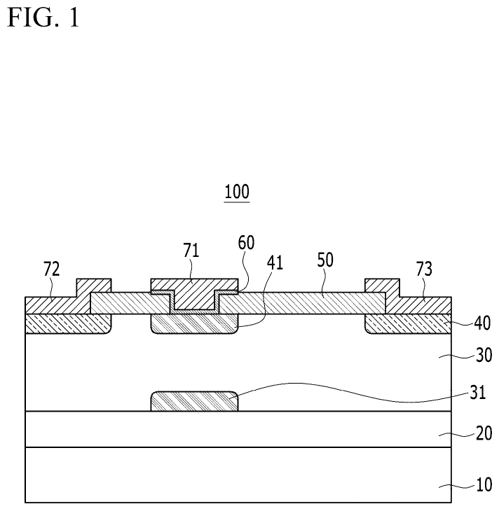

FIG. 1 is a drawing for explaining a semiconductor device according to an embodiment.

Referring to FIG. 1, a semiconductor device 100 according to an embodiment may include: a substrate 10; a first p type layer 31 and an n− type epitaxial layer 30 located on the substrate 10; an n+ type layer 40 and a second p type layer 41 located on the n− type epitaxial layer 30; a protection layer 50 located on the n+ type layer 40 and the second p type layer 41; and a gate 71; located on the protection layer 50 and on the second p type layer 41.

The substrate 10 may be a semi-insulating substrate or an insulating substrate. A semi-insulating substrate is a semiconductor material with high electrical resistance that may have properties of those between a conductive semiconductor and a completely insulating insulator. The insulating substrate may have electrically insulating properties. In some embodiments, the semi-insulating substrate may be made or composed of gallium arsenide (GaAs), silicon carbide (SiC), or the like, and the insulating substrate may be made of sapphire, glass, silicon-on-insulator (SOI) substrates.

As illustrated in FIG. 1, a buffer layer 20 may be further included on the substrate 10. The buffer layer 20 may be inevitably formed during the process of forming the n− type epitaxial layer 30 on the substrate 10.

As also illustrated in FIG. 1, the n− type epitaxial layer 30 may be located on the substrate 10. When the buffer layer 20 exists, a first n− type epitaxial layer 30 may be located on the buffer layer 20. The buffer layer 20 may include Ga₂O₃.

The n− type epitaxial layer 30 may be a major moving path of electrons when the semiconductor device 100 is in the On-state. In addition, n− type epitaxial layer 30 may be a region where a channel region depletion layer is formed, and may be a region that determines the On/Off state.

As a doping element of the n− type epitaxial layer 30, at least one of Si, Sn, and/or Ge may be used. In an embodiment, a concentration range may be in 1.0×10¹⁶ to 1.0×10¹⁹ cm⁻³. For example, the concentration range may be 0.5×10¹⁷ to 0.5×10¹⁹ cm⁻³. The base material may be Ga₂O₃.

As shown in FIG. 1, the first p type layer 31 may exist on the substrate 10. As shown in FIG. 1, the first p type layer 31 may exist in a portion of an upper surface of the substrate 10, and the n− type epitaxial layer 30 may exist in in a remaining portion thereof.

In more detail, a lower surface of the first p type layer 31 may be in contact with the upper surface of the substrate 10, and an upper surface of the first p type layer 31 may be in contact with a portion of a lower surface of the n− type epitaxial layer 30.

As a doping element of the first p type layer 31, at least one of N, Mg, Fe, Ir, and/or As may be used. In an embodiment, the concentration range may be 1.0×10¹⁶ to 1.0×10²⁰ cm⁻³. For example, the concentration range may be 0.5×10¹⁷ to 0.5×10²⁰ cm⁻³. The base material may be Ga₂O₃. As another example, the based material may be p type NiOₓ.

By forming a buried P region that floats by not being directly applied with a voltage in a lower end an epi, the first p type layer 31 may increase the breakdown voltage by alleviating the electric field concentrated at the second p type layer 41 at a lower end of the gate 7 and an end portion of the gate 71. In addition, through the buried P region that does not affect the second p type layer 41 of the lower end of the gate 7 that controls on and off of the device, a degree of freedom of device design may be increased.

In addition, the semiconductor device 100 according to an embodiment uses the ion implantation process and epitaxial process, and does not require development of new process technologies.

As illustrated in FIG. 1, the first p type layer 31 may be located in a lower portion relative to the second p type layer 41 in a thickness direction of the semiconductor device 100, interposing the n− type epitaxial layer 30.

In addition, the first p type layer 31 is located between the n− type epitaxial layers 30 separated in a horizontal direction, so that the first p type layer 31 is located to divide the n− type epitaxial layer 30 in the horizontal direction. Finally, a first end of the first p type layer 31 and a second end of the first p type layer 31 may be located to be in contact with the n− type epitaxial layer 30.

As illustrated in FIG. 1, the n+ type layer 40 and the second p type layer 41 may be located on the n− type epitaxial layer 30.

The n+ type layer 40 may be located at locations corresponding to both side portions on the n− type epitaxial layer 30. As a doping element of the n+ type layer 40, at least one of Si, Sn, and Ge may be used. The concentration range may be 1.0×10¹⁸ to 1.0×10²⁰ cm⁻³. For example, the concentration range may be 0.5×10¹⁹ to 0.5×10²⁰ cm⁻³. The base material may be Ga₂O₃.

The second p type layer 41 may be located on the n− type epitaxial layer 30. In addition, the second p type layer 41 may be located between the n− type epitaxial layers 30 separated in the horizontal direction, so that the second p type layer 41 is located to divide the n− type epitaxial layer 30 in the horizontal direction. Finally, a first end of the second p type layer 41 and a second end of the second p type layer 41 may be located to be in contact with the n− type epitaxial layer 30.

The doping element of the second p type layer 41 may be the same as the first p type layer 31. For example, as a doping element, at least one of N, Mg, Fe, Ir, and As may be used. The concentration range may be 1.0×10¹⁶ to 1.0×10²⁰ cm⁻³. For example, the concentration range may be 0.5×10¹⁷ to 0.5×10²⁰ cm⁻³. The base material may be Ga₂O₃. As another example, the base material may be p type NiOₓ.

The protection layer 50 may be located on the n+ type layer 40 and the second p type layer 41. The protection layer 50 may include at least one of SiO₂, and Si₂N₃.

As illustrated in FIG. 1, the semiconductor device 100 according to an embodiment may further include an insulation layer 60. The insulation layer 60 may be located between the second p type layer 41 and gate 71 and between the protection layer 50 and the gate 71.

More specifically, a portion of a lower surface of the insulation layer 60 may be in contact with an upper surface of the second p type layer 41, and another portion of the lower surface of the insulation layer 60 may be in contact with an upper surface of the protection layer 50. An upper surface of the insulation layer 60 may be in contact with a lower surface of the gate 71.

The insulation layer 60 may include at least one of Al₂O₃, SiO₂, HfO₂, and Si₂N₃, and may be a different material from the protection layer 50 described above.

Although FIG. 1 illustrates that the insulation layer 60 is only formed on a partial upper surface of the protection layer 50, the present disclosure is not limited thereto, and it may be formed on an entire upper surface of the protection layer 50.

The gate 71 may be located on the protection layer 50 and on the second p type layer 41. The protection layer 50 may be divided by the gate 71, and each side surface of the divided protection layer 50 may be in contact with the gate 71. When the insulation layer 60 is further included, the insulation layer 60 may exist between each side surface of the divided protection layer 50 and the gate 71.

As shown in FIG. 1, a source electrode 72 located on the protection layer 50 and the n+ type layer 40 may be further included. For example, a portion of a lower surface of the source electrode 72 may be in contact with the upper surface of the protection layer 50, and another portion of the lower surface of the source electrode 72 may be in contact with an upper surface of the n+ type layer 40.

As shown in FIG. 1, a drain electrode 73 located on the protection layer 50 and the n+ type layer 40 may be further included. For example, a portion of a lower surface of the drain electrode 73 may be in contact with the upper surface of the protection layer 50, and another portion of the lower surface of the drain electrode 73 may be in contact with the upper surface of the n+ type layer 40.

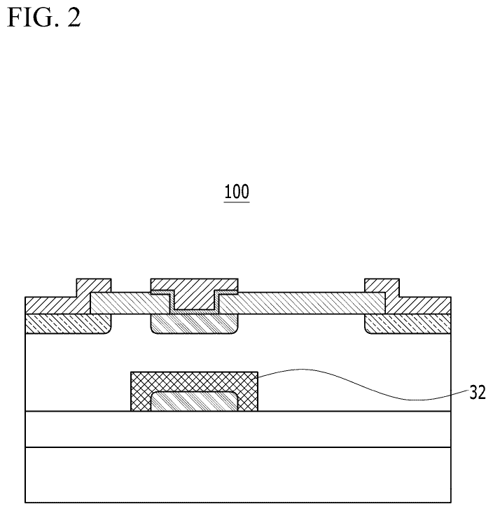

FIG. 2 schematically shows the semiconductor device 100 in an on-state, according to an embodiment. The on-state may refer to a state in which 0≤V_{DS} and Vₜₕ≤V_{GS}. V_{DS} is a voltage applied between drain—source terminals, V_{GS} is a voltage applied between gate—source terminals, and Vₜₕ is a minimum V_{GS} voltage for forming the channel.

In this state, a depletion layer 32 between a channel adjusting P region and an N− epitaxial region may be decreased by a gate voltage. Accordingly, electrons can move between the second p type layer 41 and the depletion layer 32 existing around the first p type layer 31.

In addition, the depletion layer 32 may be formed around the first p type layer 31 by a drain voltage. This allows the channel thickness to be controlled by controlling the thickness and concentration of the first p type layer 31 with the depletion layer 32 that is independent of the gate voltage and the depth and concentration of the second p type layer 41. In other words, this results in an increase in the degree of design freedom of the semiconductor device 100.

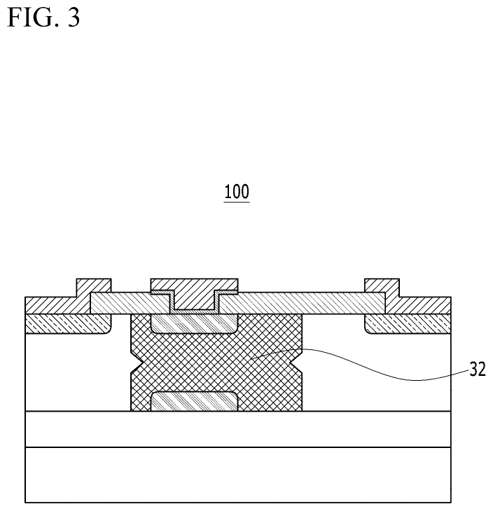

FIG. 3 schematically shows the semiconductor device 100 in an off-state. The off-state may refer to a state in which 0≤V_{DS} and Vₜₕ≥V_{GS}.

In the off-state, the depletion layer 32 between the channel adjusting P region and the N− epitaxial region may be increased by the drain voltage.

By the drain voltage, the depletion layer 32 may be formed around the first p type layer 31 and the second p type layer 41, and by the high drain voltage, the depletion layer 32 between PN junctions may increase. Therefore, the depletion layer 32 formed around the first p type layer 31 and the second p type layer 41 blocks the electron moving path of the channel.

An end of the gate 71 of a portion adjacent to the drain electrode 73 and electric field of a second p type layer 31 may be dispersed due to the existence of the first p type layer 31, thereby alleviating the electric field.

A manufacturing method of the semiconductor device 100 according to an embodiment may include: providing the substrate 10; forming the n− type epitaxial layer 30 and the first p type layer 31 on the substrate 10; forming the n+ type layer 40 and the second p type layer 41 on the n− type epitaxial layer 30; forming the protection layer 50 on the n+ type layer 40 and the second p type layer 41; and partially removing the protection layer 50 located on the second p type layer 41, and forming the gate 71 on the second p type layer 41 and on the protection layer 50.

Hereinafter, each process, according to an embodiment, is described in detail.

First, the substrate 10 may be provided. Since the substrate 10 has been described above, a detailed description thereof is not included herein.

Subsequently, the first n− type epitaxial layer 30 and the first p type layer 31 may be formed on the substrate 10. The first n− type epitaxial layer 30 may be formed by injecting ions such as Si, Sn, and Ge. At this time, the buffer layer 20 may be inevitably formed on the substrate 10.

The forming the first n− type epitaxial layer 30 and the first p type layer 31 may be implemented in various methods, and is not particularly limited.

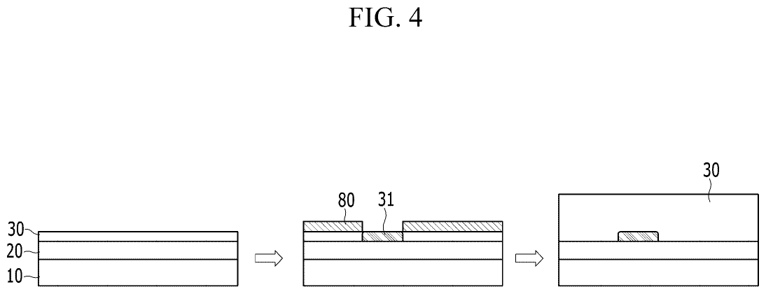

FIG. 4 schematically shows an example of forming the first n− type epitaxial layer 30 and the first p type layer 31, according to an embodiment. As shown in FIG. 4, the forming the n− type epitaxial layer 30 and the first p type layer 31 on the substrate 10 may include: forming the n− type epitaxial layer 30 by growing an epitaxial layer on the substrate 10; forming the first p type layer 31 by injecting ions into a portion of the n− type epitaxial layer 30; and re-growing the epitaxial layer on the n− type epitaxial layer 30 and the first p type layer 31.

As shown in FIG. 4, when injecting ions into a portion of the n− type epitaxial layer 30, the first p type layer 31 may be formed at a particular location, by forming a pattern of a photosensitive layer 80.

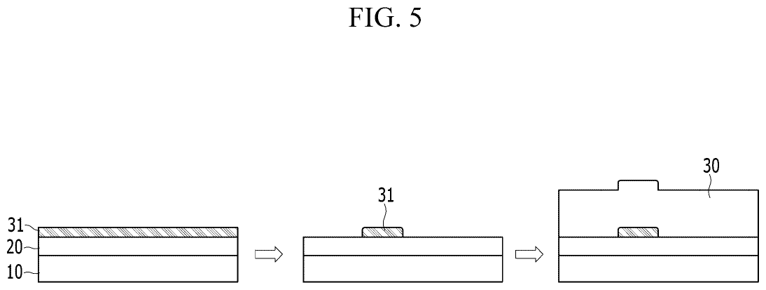

FIG. 5 schematically shows another example of forming the first n− type epitaxial layer 30 and the first p type layer 31, according to another embodiment. As shown in FIG. 5, the forming the n− type epitaxial layer 30 and the first p type layer 31 on the substrate 10 may include: forming the first p type layer 31 on the substrate 10; partially removing the first p type layer 31; and forming the n− type epitaxial layer 30 by growing an epitaxial layer on a remaining first p type layer and the substrate 10.

As shown in FIG. 5, the first p type layer 31 may be formed by forming the first p type layer 31 on the entire upper surface of the substrate 10, and then partially removing the first p type layer 31, leaving a remaining portion of the first p type layer 31 on the upper surface of the substrate 10.

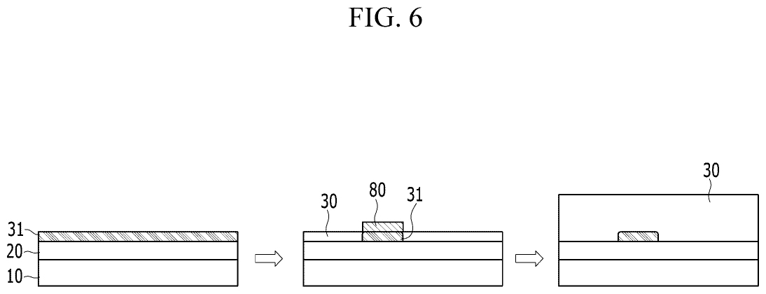

FIG. 6 schematically shows still another example of forming the first n-type epitaxial layer 30 and the first p type layer 31, according to still another embodiment. As shown in FIG. 6, the forming the n− type epitaxial layer 30 and the first p type layer 31 on the substrate 10 may include: forming the first p type layer 31 on the substrate 10; forming the n− type epitaxial layer 30 by injecting ions into a portion of the first p type layer 31; and forming the n− type epitaxial layer 30 by growing an epitaxial layer on a remaining first p type layer 31 and the n− type epitaxial layer 30.

As shown in FIG. 6, when injecting ions into a portion of the first p type layer 31, the n− type epitaxial layer 30 may be formed at a particular location, by forming a pattern of the photosensitive layer 80.

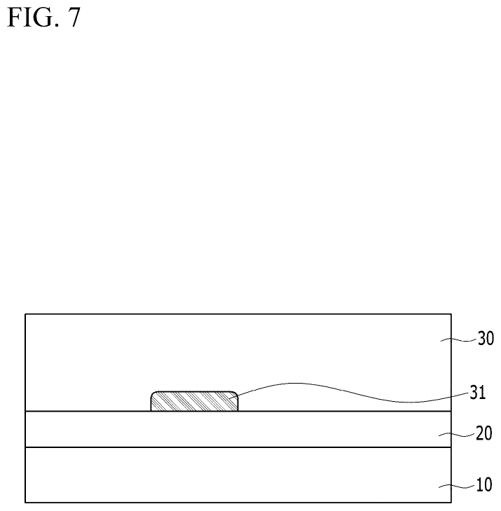

FIG. 7 is a drawing schematically showing process after forming the n-type epitaxial layer 30 and the first p type layer 31, in a method of manufacturing a semiconductor device according to an embodiment.

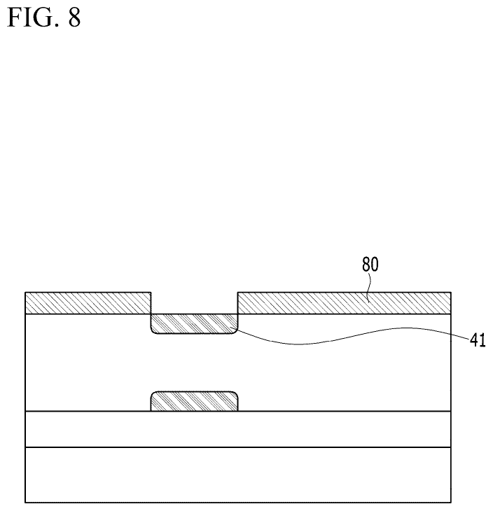

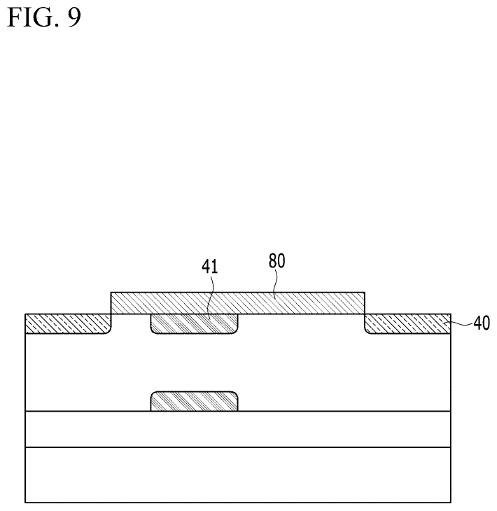

Subsequently, the n+ type layer 40 and the second p type layer 41 may be formed on the n− type epitaxial layer. As shown in FIGS. 8 and 9, the n+ type layer 40 may be formed after forming the second p type layer 41, but it is not limited thereto, and the n+ type layer 40 may be formed first, or the n+ type layer 40 and the second p type layer 41 may be simultaneously formed.

As shown in FIGS. 8 and 9, in order to form the n+ type layer 40 and the second p type layer 41 at appropriate locations, the photosensitive layer 80 may be patterned. The n+ type layer 40 and the second p type layer may be formed through appropriate ion implantation.

Subsequently, the protection layer 50 on the n+ type layer 40 and the second p type layer 41 may be formed.

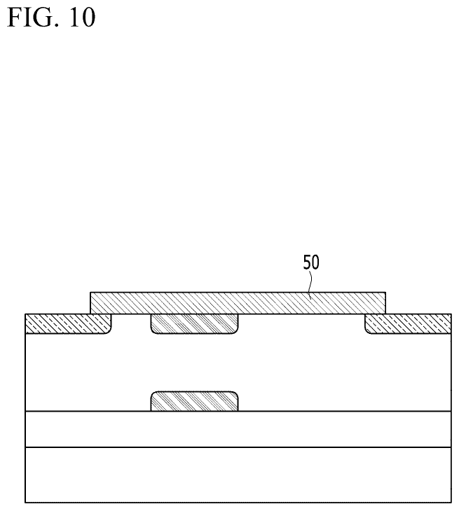

FIG. 10 shows a drawing after forming the protection layer 50, according to an embodiment.

Forming the protection layer 50, and forming the insulation layer 60 on the second p type layer 41 and on the protection layer 50 may be further included.

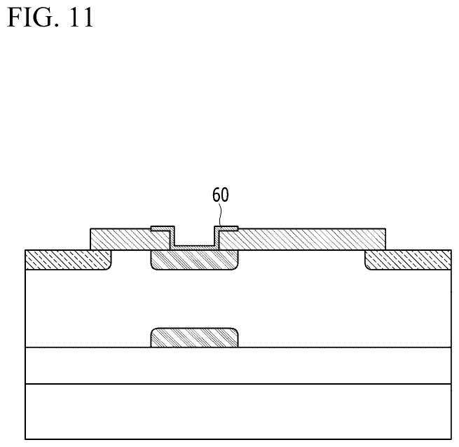

When the forming the insulation layer 60 is further included, the gate 71 may be formed on the insulation layer 60. FIG. 11 shows a drawing after forming the insulation layer 60, according to an embodiment.

Subsequently, the protection layer 50 located on the second p type layer 41 may be partially removed, and the gate 71 may be formed on second p type layer 41 and on the protection layer 50.

The gate 71 may be formed of polysilicon, and as needed, a metal material may be used.

The gate 71 may be formed by the following two methods.

As one method, before forming the gate 71, forming the insulation layer 60 on the second p type layer 41 and on the protection layer 50 may be further included, and the forming the gate 71 may form the gate 71 on the insulation layer 60.

As another method, before forming the gate 71, forming a photosensitive layer, an insulation layer, and a metal layer on the protection layer 50 may be further included, and the forming the gate 71 may be performed by patterning and then removing the insulation layer and the metal layer on the photosensitive layer and the photosensitive layer. During this process, a desired gate region may be precisely patterned by using the photolithography technology.

In an embodiment, forming the source electrode 72 on the protection layer 50 and the n+ type layer 40 and forming the drain electrode 73 on the protection layer 50 and the n+ type layer 40 may be further included. A detailed forming method is as follows.

First, the photosensitive layer may be applied on the protection layer 50 and the gate 71, and patterned, and the protection layer 50 may be partially etched. At this time, the etched protection layer 50 may be located in both end portions of the protection layer 50, which will become the locations where the source electrode 72 and the drain electrode 73 are formed, respectively.

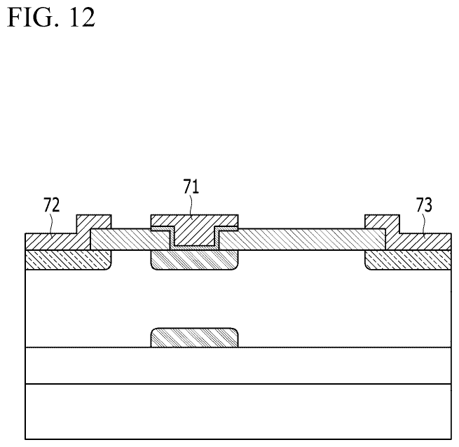

FIG. 12 shows a drawing after the gate 71, the source electrode 72, and the drain electrode 73 are formed.

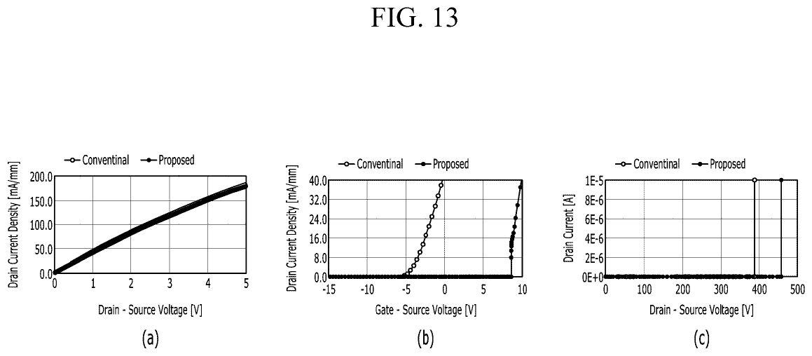

FIG. 13 shows measurement results of a state current (a), a threshold voltage (b), and a breakdown voltage (c), according to an embodiment.

In FIG. 13, the semiconductor device indicated as “conventional” or “Comparative Example” did not form the first p type layer 31, unlike the semiconductor device of an embodiment, and the corresponding location exists as the n− type epitaxial layer 30.

The data indicated as “Proposed” in FIG. 13 denotes a semiconductor device having a structure represented in FIG. 1.

In addition, in the following Table 1, semiconductor devices according to a Comparative Example and an embodiment are used, where a current density, a threshold voltage, a breakdown voltage, and a figure of merit are measured with respect to the semiconductor device of an embodiment.

The results are presented by using Sentaurus TCAD from Synopsys.

TABLE 1

| Classification | Embodiment | Comparative Example |
|---|---|---|
| Current density [mA/mm] | 100.54 | 102.15 |
| Threshold voltage [V] | 8.61 | −3.23 |
| Breakdown voltage [V] | 457.9 | 387.2 |
| Figure of merit [MW/mm] | 8.43 | 6.13 |

As shown in Table 1 and FIG. 13, it may be confirmed that the breakdown voltage increased by adding the first p type layer 31. Specifically, the breakdown voltage increased by 18.3%.

In addition, it was confirmed that the current density was partially decreased. Specifically, the current density decreased by 1.58%. However, the current increased at an equivalent breakdown voltage, due to the trade-off relationship of breakdown voltage—current density. However, it was confirmed that the figure of merit of power semiconductor has been improved by 37.6%.

Finally, it may be confirmed that the threshold voltage increased by adding the first p type layer 31. It was confirmed that the threshold voltage increased 366.5%, and the normally-off operation may be implemented.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of appended claims.

What is claimed is:

1. A semiconductor device, comprising:
a substrate;
a first p type layer and an n− type epitaxial layer located on the substrate;
an n+ type layer and a second p type layer located on the n− type epitaxial layer;
a protection layer located on the n+ type layer and the second p type layer; and
a gate located on the protection layer and on the second p type layer.

2. The semiconductor device of claim 1, further comprising an insulation layer,
wherein the insulation layer is located between the second p type layer and the gate and between the protection layer and the gate.

3. The semiconductor device of claim 2, wherein:
a portion of a lower surface of the insulation layer is in contact with an upper surface of the second p type layer, and another portion of the lower surface of the insulation layer is in contact with an upper surface of the protection layer; and
a portion of an upper surface of the insulation layer is in contact with a lower surface of the gate.

4. The semiconductor device of claim 1, wherein:
a lower surface of the first p type layer is in contact with an upper surface of the substrate; and
an upper surface of the first p type layer is in contact with a portion of a lower surface of the n− type epitaxial layer.

5. The semiconductor device of claim 1, wherein the first p type layer is located in a lower portion relative to the second p type layer in a thickness direction of the semiconductor device, interposing the n− type epitaxial layer.

6. The semiconductor device of claim 1, wherein the protection layer is divided by the gate.

7. The semiconductor device of claim 1, further comprising a source electrode located on the protection layer and the n+ type layer,
wherein a portion of a lower surface of the source electrode is in contact with an upper surface of the protection layer, and another portion of the lower surface of the source electrode is in contact with an upper surface of the n+ type layer.

8. The semiconductor device of claim 1, further comprising a drain electrode located on the protection layer and the n+ type layer,
wherein a portion of a lower surface of the drain electrode is in contact with an upper surface of the protection layer, and another portion of the lower surface of the drain electrode is in contact with an upper surface of the n+ type layer.

9. The semiconductor device of claim 1, further comprising a buffer layer located between the substrate and the n− type epitaxial layer, wherein a lower surface of the first p type layer and a portion of an upper surface of the buffer layer are in contact with the n-type epitaxial layer.

10. A method of manufacturing a semiconductor device, the method comprising:
providing a substrate;
forming an n− type epitaxial layer and a first p type layer on the substrate;
forming n+ type layer and a second p type layer on the n− type epitaxial layer;
forming a protection layer on the n+ type layer and the second p type layer; and
partially removing the protection layer located on the second p type layer and forming a gate on the second p type layer and on the protection layer.

11. The method of claim 10, wherein forming the n− type epitaxial layer and the first p type layer on the substrate comprises:
forming the n− type epitaxial layer by growing an epitaxial layer on the substrate;
forming the first p type layer by injecting ions into a portion of the n− type epitaxial layer; and
re-growing the epitaxial layer on the n− type epitaxial layer and the first p type layer.

12. The method of claim 10, wherein forming the n− type epitaxial layer and the first p type layer on the substrate comprises:
forming the first p type layer on the substrate;
partially removing the first p type layer; and
forming the n− type epitaxial layer by growing an epitaxial layer on a remaining first p type layer and the substrate.

13. The method of claim 10, wherein forming the n− type epitaxial layer and the first p type layer on the substrate comprises:
forming the first p type layer on the substrate;
forming the n− type epitaxial layer by injecting ions into a portion of the first p type layer; and
forming the n− type epitaxial layer by growing the epitaxial layer on a remaining first p type layer and the n− type epitaxial layer.

14. The method of claim 10, further comprising, before forming the gate, forming an insulation layer on the second p type layer and on the protection layer,
wherein forming the gate forms the gate on the insulation layer.

15. The method of claim 10, further comprising:
forming a source electrode on the protection layer and the n+ type layer and
forming a drain electrode on the protection layer and the n+ type layer.

16. The method of claim 10, further comprising, after the providing the substrate, forming a buffer layer on the substrate.
